(19) United States
(12) Patent Application Publication
(10) Pub. No.: US 2026/0074668 A1
(43) Pub. Date: Mar. 12, 2026

(54) ELECTRONIC COMPONENT

(71) Applicant: TDK CORPORATION, Tokyo (JP)

(72) Inventors: Masato YAMAGUCHI, Tokyo (JP); Takuya Sato, Tokyo (JP)

(73) Assignee: TDK CORPORATION, Tokyo (JP)

(21) Appl. No.: 19/300,155

(22) Filed: Aug. 14, 2025

(30) Foreign Application Priority Data
Sep. 11, 2024 (JP) 2024-157426

(51) Int. Cl. H03H 7/01; H01F 17/00; H01F 27/28

(52) U.S. Cl. CPC H03H 7/1758; H01F 17/0013; H01F 27/28; H03H 7/0115; H01F 2017/002; H01F 2017/0026

(57) ABSTRACT

An electronic component includes a first main body, and a second main body mounted on the first main body. The first main body includes a first circuit section, a second circuit section, and a first structure and a second structure each connected to the ground. The second main body includes a first sub-circuit section and a second sub-circuit section electrically separated from each other. The first structure includes a first conductor layer located between the first circuit section and the second circuit section. The second structure includes a second conductor layer overlapping a region located between the first sub-circuit section and the second sub-circuit section. The first conductor layer is not directly connected to the second conductor layer.

### CROSS REFERENCE TO RELATED APPLICATIONS

This application claims the benefit of Japanese Priority Patent Application No. 2024-157426 filed on Sep. 11, 2024, the entire contents of which are incorporated herein by reference.

### BACKGROUND

The disclosure relates to an electronic component including a main body and a mounted component mounted on the main body.

For compact mobile communication apparatuses, a configuration is widely used in which a common antenna for a plurality of applications that use different systems and have different service frequency bands is provided, and a branching filter is used to separate a plurality of signals received and transmitted by the antenna from each other.

A branching filter for separating a first signal of a frequency within a first frequency band and a second signal of a frequency within a second frequency band higher than the first frequency band from each other typically includes a common port, a first signal port, a second signal port, a first filter provided in a first signal path leading from the common port to the first signal port, and a second filter provided in a second signal path leading from the common port to the second signal port.

As resonators used in the first and second filters, for example, an LC resonator configured using an inductor and a capacitor, and an acoustic wave resonator configured using an acoustic wave element are known. The acoustic wave element is an element using an acoustic wave. Examples of the acoustic wave element include a surface acoustic wave element using a surface acoustic wave and a bulk acoustic wave element using a bulk acoustic wave. For example, JP 2017-112525 A and JP 2017-135445 A disclose a branching filter configured using a stack including an LC resonator, and two acoustic wave resonators mounted on a top surface of the stack.

In recent years, the market has been demanding downsizing and space-saving of compact mobile communication apparatuses, and there is also a demand for downsizing of branching filters used in the communication apparatuses. In a branching filter configured using a stack, in order to suppress coupling between a first element included in the first filter and a second element included in the second filter, it is considered to provide a partition connected to the ground, between the first element and the second element. The partition may be a structure configured by a plurality of conductor layers and a plurality of through holes. If the branching filter is downsized, a distance between each of the first and second elements and the partition becomes small. As a result, unintended flowing of a current may occur between the first element or the second element and the other element via the partition, and the desired characteristics could not be achieved in some cases.

The above problem applies not only to the branching filter but also to electronic components in general that include a plurality of elements separated from each other by a partition. In particular, as the branching filters described in JP 2017-112525 A and JP 2017-135445 A, in the electronic components in which a second main body is mounted on a first main body, if unintended flowing of a current occurs between an element of the first main body and an element of the second main body, it is further difficult to achieve the desired characteristics.

### SUMMARY

An electronic component according to one embodiment of the disclosure includes: a first main body including a plurality of dielectric layers stacked together; and a second main body mounted on the first main body. The first main body further includes a first circuit section, a second circuit section, and a first structure and a second structure each connected to a ground. The second main body includes a first sub-circuit section and a second sub-circuit section electrically separated from each other. The first structure includes a first conductor layer located between the first circuit section and the second circuit section when viewed in a stacking direction of the plurality of dielectric layers. The second structure includes a second conductor layer overlapping a region located between the first sub-circuit section and the second sub-circuit section when viewed in the stacking direction. The first conductor layer is not directly connected to the second conductor layer.

Objects, features, and advantages of the disclosure will appear more fully from the following description.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the technology.

FIG. 1 is a block diagram showing a configuration of an electronic component according to an example embodiment of the disclosure.

FIG. 2 is a perspective view showing the electronic component according to the example embodiment of the disclosure.

FIG. 3 is a perspective view showing a first main body in the example embodiment of the disclosure.

FIG. 4 is a plan view showing the first main body in the example embodiment of the disclosure.

FIG. 5 is a plan view showing a part inside the first main body in the example embodiment of the disclosure.

FIG. 6 is a perspective view showing a part inside the first main body in the example embodiment of the disclosure.

FIG. 7 is a plan view showing a part inside a first main body of an electronic component of a comparative example.

FIG. 8 is a circuit diagram showing a circuit configuration in a model of an example used in a simulation.

FIG. 9 is a characteristic chart showing frequency characteristics of isolation of each of a model of the example and a model of the comparative example determined by the simulation.

### DETAILED DESCRIPTION

An object of the disclosure is to provide an electronic component in which a second main body is mounted on a first main body, and which is capable of suppressing deterioration of characteristics associated with downsizing.

In the following, some example embodiments and modification examples of the technology are described in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions.

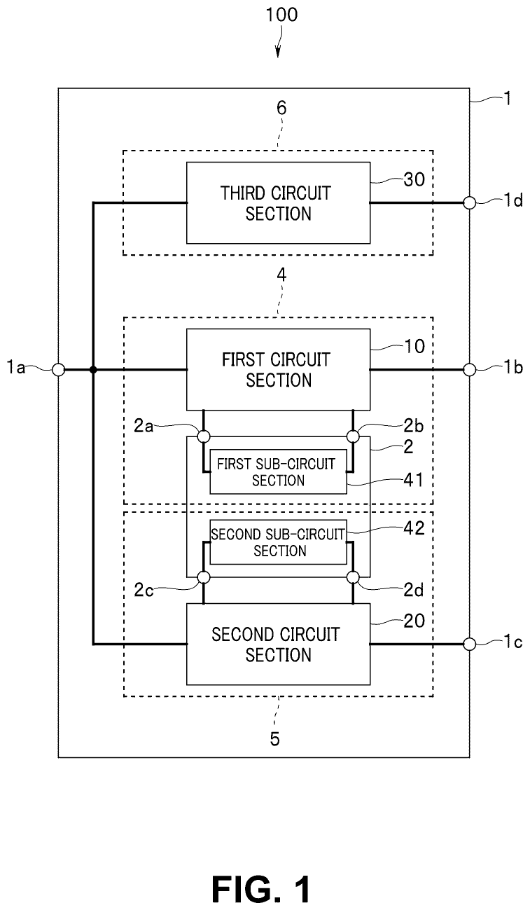

Initially, a schematic configuration of an electronic component 100 according to an example embodiment of the disclosure will be described with reference to FIG. 1. FIG. 1 is a block diagram showing a configuration of the electronic component 100.

The electronic component 100 according to the example embodiment is a branching filter (triplexer) including a first filter 4, a second filter 5, and a third filter 6. The first filter 4 is configured to selectively pass a first signal of a frequency within a first passband. The second filter 5 is configured to selectively pass a second signal of a frequency within a second passband different from the first passband. The third filter 6 is configured to selectively pass a third signal of a frequency within a third passband different from each of the first passband and the second passband. In the example embodiment, in particular, the second passband is a frequency band higher than the first passband, and the third passband is a frequency band lower than the first passband.

The first filter 4 includes a first circuit section 10. The second filter 5 includes a second circuit section 20. The third filter 6 includes a third circuit section 30. Each of the first to third circuit sections 10, 20, and 30 is an LC circuit including at least one inductor and at least one capacitor.

The first filter 4 further includes a first sub-circuit section 41. The second filter 5 further includes a second sub-circuit section 42. The first circuit section 10 is connected to the first sub-circuit section 41. The second circuit section 20 is connected to the second sub-circuit section 42. The first and second sub-circuit sections 41 and 42 are electrically separated from each other. Note that the expression “electrically separated” may mean that the first sub-circuit section 41 and the second circuit section 20 are not connected by a conductor. The first and second sub-circuit sections 41 and 42 each include at least one acoustic wave element. Examples of the acoustic wave element may include, for example, a bulk acoustic wave element and a surface acoustic wave element. Each of the first and second sub-circuit sections 41 and 42 may be an acoustic wave resonator.

The first circuit section 10 and the first sub-circuit section 41 constitute one filter circuit (first filter 4). The second circuit section 20 and the second sub-circuit section 42 constitute another filter circuit (second filter 5).

The electronic component 100 further includes a common terminal 1a, a first signal terminal 1b, a second signal terminal 1c, and a third signal terminal 1d. The first filter 4 is provided between the common terminal 1a and the first signal terminal 1b in a circuit configuration. The second filter 5 is provided between the common terminal 1a and the second signal terminal 1c in the circuit configuration. The third filter 6 is provided between the common terminal 1a and the third signal terminal 1d in the circuit configuration. Note that in the present application, the expression “in the (a) circuit configuration” is used to indicate not layout in the physical configuration but layout in the circuit diagram.

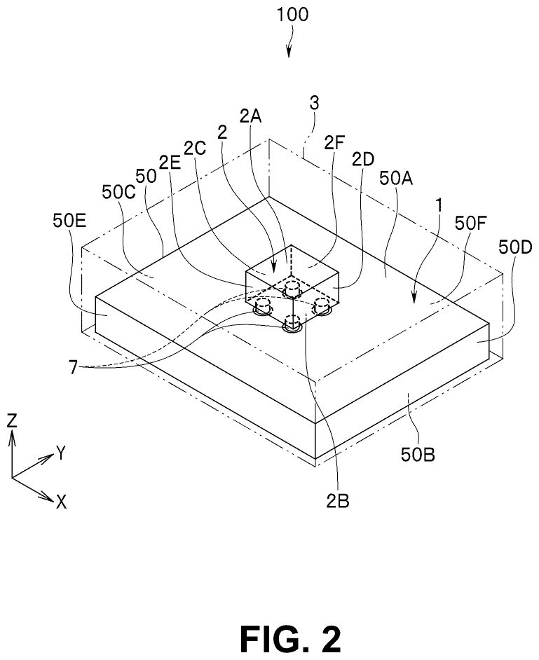

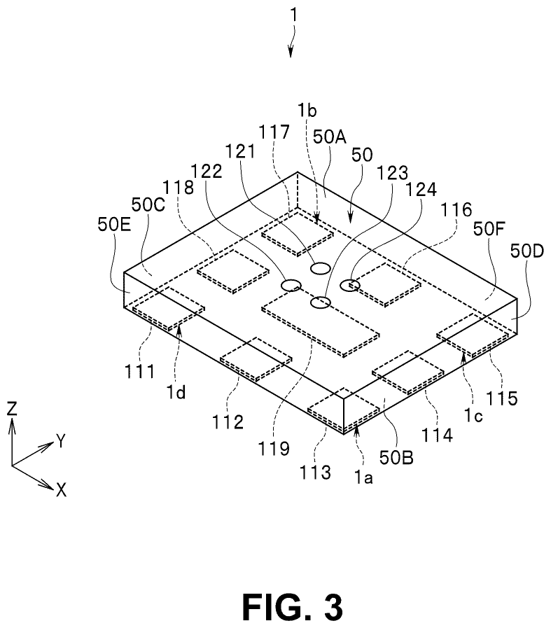

Next, the configuration of the electronic component 100 will be specifically described with reference to FIG. 1 to FIG. 3. FIG. 2 is a perspective view showing the electronic component 100. FIG. 3 is a perspective view showing a first main body in the example embodiment. As shown in FIG. 2, the electronic component 100 includes a first main body 1, a second main body 2 mounted on the first main body 1, and a sealing portion 3 that seals the first and second main bodies 1 and 2. The sealing portion 3 is formed of a resin, for example.

The first main body 1 includes the first to third circuit sections 10, 20, and 30 shown in FIG. 1. The first main body 1 also includes a stack 50. The stack 50 includes a plurality of dielectric layers stacked together, and a plurality of conductor layers and a plurality of through holes formed on/in the plurality of dielectric layers. The LC circuits of the respective first to third circuit sections 10, 20, and 30 are configured using the plurality of dielectric layers, the plurality of conductor layers, and the plurality of through holes.

The plurality of through holes are formed by filling holes for forming respective through holes with a conductive paste. Each of the plurality of through holes is connected to an electrode, a conductor layer, or another through hole.

The stack 50 includes a first surface 50A and a second surface 50B located at both ends of the plurality of dielectric layers in a stacking direction, and four side surfaces 50C to 50F connecting the first and second surfaces 50A and 50B. The side surfaces 50C and 50D are directed opposite to each other, and the side surfaces 50E and 50F are also directed opposite to each other. The side surfaces 50C to 50F are perpendicular to the first and second surfaces 50A and 50B.

Here, an X direction, a Y direction, and a Z direction will be defined as shown in FIG. 2 and FIG. 3. The X, Y, and Z directions are orthogonal to one another. In the example embodiment, a direction parallel to the stacking direction will be referred to as the Z direction. The Z direction is also a direction parallel to a direction in which the first and second main bodies 1 and 2 are arranged. A direction opposite to the X direction will be referred to as a −X direction, a direction opposite to the Y direction as a −Y direction, and a direction opposite to the Z direction as a −Z direction. The expression “when seen in a specific direction (the stacking direction, for example)” means that the intended object is seen from a position away in the specific direction or a direction parallel to the specific direction.

As shown in FIG. 3, the first surface 50A is located at the end of the stack 50 in the Z direction. The first surface 50A is also a part of outer surfaces of the first main body 1 on which the second main body 2 is mounted, and is a top surface of the stack 50. The second surface 50B is located at the end of the stack 50 in the −Z direction. The second surface 50B is a surface opposite to the first surface 50A, and is also a bottom surface of the stack 50. The side surface 50C is located at the end of the stack 50 in the −X direction. The side surface 50D is located at the end of the stack 50 in the X direction. The side surface 50E is located at the end of the stack 50 in the −Y direction. The side surface 50F is located at the end of the stack 50 in the Y direction.

The first main body 1 further includes a plurality of electrodes 111, 112, 113, 114, 115, 116, 117, 118, and 119 provided on the second surface 50B of the stack 50. The electrode 111 is disposed near the corner that exists at a position where the second surface 50B, the side surface 50C, and the side surface 50E intersect. The electrode 113 is disposed near the corner that exists at a position where the second surface 50B, the side surface 50D, and the side surface 50E intersect. The electrode 115 is disposed near the corner that exists at a position where the second surface 50B, the side surface 50D, and the side surface 50F intersect. The electrode 117 is disposed near the corner that exists at a position where the second surface 50B, the side surface 50C, and the side surface 50F intersect.

The electrode 112 is disposed between the electrodes 111 and 113. The electrode 114 is disposed between the electrodes 113 and 115. The electrode 116 is disposed between the electrodes 115 and 117. The electrode 118 is disposed between the electrodes 111 and 117. The electrode 119 is disposed at the center or at substantially the center of the second surface 50B.

The first main body 1 further includes the common terminal 1a, the first signal terminal 1b, the second signal terminal 1c, and the third signal terminal 1d shown in FIG. 1. The electrode 111 corresponds to the third signal terminal 1d, the electrode 113 corresponds to the common terminal 1a, the electrode 115 corresponds to the second signal terminal 1c, and the electrode 117 corresponds to the first signal terminal 1b. The common terminal 1a and the first to third signal terminals 1b to 1d are thus provided on the second surface 50B of the stack 50. Each of the electrodes 112, 114, 116, 118, and 119 is connected to the ground.

The first main body 1 further includes four electrode pads 121, 122, 123, and 124 provided on the first surface 50A of the stack 50. The electrode pads 121 to 124 may be disposed near the center of the first surface 50A. The electrode pads 121 and 122 are arranged in this order in the −Y direction. The electrode pads 123 and 124 are arranged in this order in the Y direction at positions on the X direction side relative to the electrode pads 121 and 122.

The second main body 2 includes the first and second sub-circuit sections 41 and 42. Moreover, the second main body 2 includes a third surface 2A and a fourth surface 2B located at both ends in the direction parallel to the Z direction, and four side surfaces 2C to 2F connecting the third and fourth surfaces 2A and 2B. The side surfaces 2C and 2D are directed opposite to each other, and the side surfaces 2E and 2F are also directed opposite to each other. The side surfaces 2C to 2F are perpendicular to the third and fourth surfaces 2A and 2B.

As shown in FIG. 2, the third surface 2A is located at the end of the second main body 2 in the Z direction. The third surface 2A is also a top surface of the second main body 2. The fourth surface 2B is located at the end of the second main body 2 in the −Z direction. The fourth surface 2B is a surface facing the first main body 1, and is also a bottom surface of the second main body 2. The side surface 2C is located at the end of the second main body 2 in the −X direction. The side surface 2D is located at the end of the second main body 2 in the X direction. The side surface 2E is located at the end of the second main body 2 in the −Y direction. The side surface 2F is located at the end of the second main body 2 in the Y direction.

The second main body 2 further includes a first terminal 2a, a second terminal 2b, a third terminal 2c, and a fourth terminal 2d disposed on the fourth surface 2B of the second main body 2. The first terminal 2a is disposed near the corner that exists at a position where the fourth surface 2B, the side surface 2C, and the side surface 2F intersect. The second terminal 2b is disposed near the corner that exists at a position where the fourth surface 2B, the side surface 2C, and the side surface 2E intersect. The third terminal 2c is disposed near the corner that exists at a position where the fourth surface 2B, the side surface 2D, and the side surface 2E intersect. The fourth terminal 2d is disposed near the corner that exists at a position where the fourth surface 2B, the side surface 2D, and the side surface 2F intersect.

The first sub-circuit section 41 is provided between the first and second terminals 2a and 2b in the circuit configuration. The second sub-circuit section 42 is provided between the third and fourth terminals 2c and 2d in the circuit configuration.

In the state where the second main body 2 is mounted on the first main body 1, the first to fourth terminals 2a, 2b, 2c, and 2d of the second main body 2 respectively face the electrode pads 121, 122, 123, and 124 of the first main body 1. The first to fourth terminals 2a, 2b, 2c, and 2d are respectively connected to the electrode pads 121, 122, 123, and 124 via a conductive bonding material. In the example embodiment, in particular, the first to fourth terminals 2a, 2b, 2c, and 2d are electrically and physically connected respectively to the electrode pads 121, 122, 123, and 124 by a solder bump 7, for example.

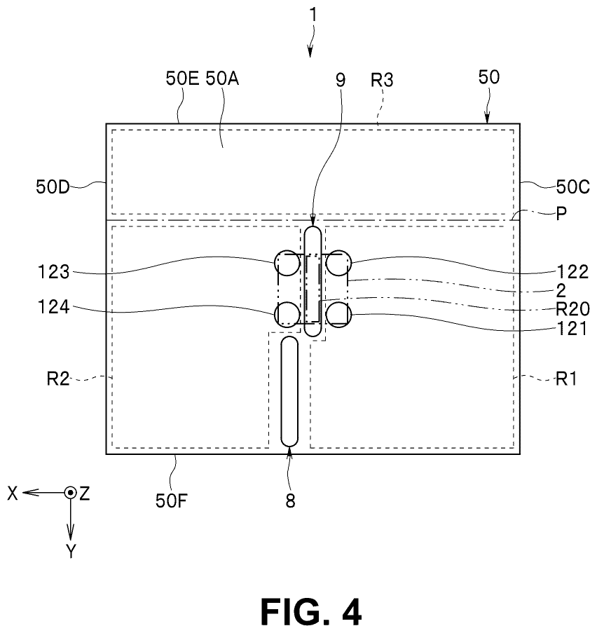

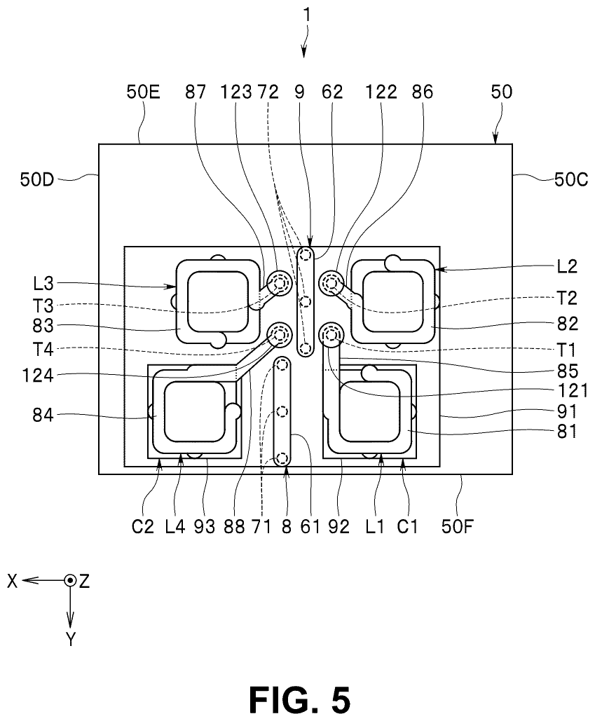

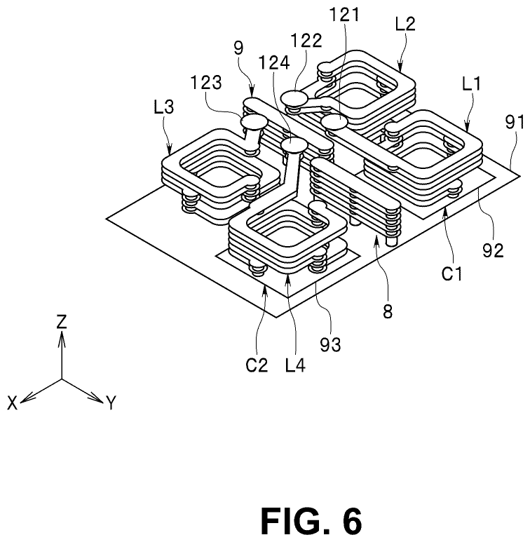

Next, the first main body 1 will be described in more detail with reference to FIG. 4 to FIG. 6. FIG. 4 is a plan view showing the first main body 1. FIG. 5 is a plan view showing a part inside the first main body 1. FIG. 6 is a perspective view showing a part inside the first main body 1.

The first main body 1 further includes a first structure 8 and a second structure 9 each connected to the ground. The second structure 9 is disposed between the electrode pad 121 and the electrode pad 124 and between the electrode pad 122 and the electrode pad 123 when seen in the Z direction. The electrode pads 121 and 122 are disposed forward of the second structure 9 in the −X direction when seen in the Z direction. The electrode pads 123 and 124 are disposed forward of the second structure 9 in the X direction when seen in the Z direction. The first structure 8 is disposed between the second structure 9 and the side surface 50F.

Here, a three-dimensional region within the stack 50 defined by the first and second structures 8 and 9 and a boundary surface P will be described with reference to FIG. 4. The boundary surface P is an imaginary plane parallel to an XZ plane and located between the first and second structures 8 and 9 and the side surface 50E. The boundary surface P may be located closer to the second structure 9 than to the side surface 50E.

The stack 50 includes a first region R1, a second region R2, and a third region R3. The first region R1 is a region surrounded by the first and second structures 8 and 9, the side surfaces 50C and 50F, and the boundary surface P. The second region R2 is a region surrounded by the first and second structures 8 and 9, the side surfaces 50D and 50F, and the boundary surface P. The third region R3 is a region surrounded by the side surfaces 50C, 50D, and 50E and the boundary surface P. In FIG. 4, a region surrounded by a broken line denoted by the reference sign R1 indicates the first region R1, a region surrounded by a broken line denoted by the reference sign R2 indicates the second region R2, and a region surrounded by a broken line denoted by the reference sign R3 indicates the third region R3. The first and second structures 8 and 9 are used as partitioning portions to partition the first region R1 and the second region R2.

The first region R1 is a region including at least a part of the first circuit section 10 but not including the second circuit section 20. The second region R2 is a region including at least a part of the second circuit section 20 but not including the first circuit section 10. The third region R3 is a region including the third circuit section 30. The third region R3 may or does not have to include another part of the first circuit section 10 and another part of the second circuit section 20.

Next, structures of the first and second structures 8 and 9 will be described with reference to FIG. 5 and FIG. 6. The first structure 8 includes a plurality first through holes 71, and a plurality of first conductor layers 61 electrically connected to the plurality of first through holes 71. The plurality of first conductor layers 61 are disposed at different positions from each other in the direction parallel to the stacking direction, that is, the Z direction. The second structure 9 includes a plurality of second through holes 72, and a plurality of second conductor layers 62 electrically connected to the plurality of second through holes 72. The plurality of second conductor layers 62 are disposed at different positions from each other in the direction parallel to the stacking direction, that is, the Z direction. Note that the expression “electrically connected” may mean that two component are connected directly or via a conductor, or may mean that a conductor between two components is not disconnected.

Each of the plurality of first conductor layers 61 and the plurality of second conductor layers 62 includes a part extending along the same direction orthogonal to the stacking direction. In the example embodiment, in particular, each of the plurality of first conductor layers 61 and the plurality of second conductor layers 62 extends as a whole along a direction parallel to the Y direction.

In addition, the shapes of the plurality of first conductor layers 61 are the same as one another. The positions of the plurality of first conductor layers 61 are the same except for their positions in the stacking direction. Two first conductor layers 61 adjacent to each other at a distance in the stacking direction are connected to each other by at least one first through hole 71. In the example shown in FIG. 5 and FIG. 6, the above two first conductor layers 61 are connected to each other by three first through holes 71.

In addition, the shapes of the plurality of second conductor layers 62 are the same as one another. The positions of the plurality of second conductor layers 62 are the same except for their positions in the stacking direction. Two second conductor layers 62 adjacent to each other at a distance in the stacking direction are connected to each other by at least one second through hole 72. In the example shown in FIG. 5 and FIG. 6, the above two second conductor layers 62 are connected to each other by three second through holes 72.

The plurality of first conductor layers 61 include a specific first conductor layer 61. The specific first conductor layer 61 may be, for example, a conductor layer closest to the first surface 50A of the plurality of first conductor layers 61. Since the plurality of first conductor layers 61 are components of the first structure 8, it can be said that the first structure 8 includes the specific first conductor layer 61. In FIG. 5, the reference sign 61 indicates the specific first conductor layer 61.

The plurality of second conductor layers 62 include a specific second conductor layer 62. The specific second conductor layer 62 may be, for example, a conductor layer closest to the first surface 50A of the plurality of the second conductor layers 62. Since the plurality of second conductor layers 62 are components of the second structure 9, it can be said that the second structure 9 includes the specific second conductor layer 62. In FIG. 5, the reference sign 62 indicates the specific second conductor layer 62.

The specific first conductor layer 61 and the specific second conductor layer 62 are located between the first region R1 and the second region R2, and between the first circuit section 10 and the second circuit section 20, when viewed in the stacking direction (the direction parallel to the Z direction). As shown in FIG. 5, the specific first conductor layer 61 is not directly connected to the specific second conductor layer 62.

In the example embodiment, in particular, the above description of the specific first conductor layer 61 applies to the first conductor layers 61 other than the specific first conductor layer 61. Similarly, the above description of the specific second conductor layer 62 applies to the second conductor layers 62 other than the specific second conductor layer 62. The first conductor layers 61 are not directly connected to the second conductor layers 62 located at the same position in the stacking direction.

Next, features of the first and second structures 8 and 9 and the first and second circuit sections 10 and 20 will be described with reference to FIG. 4 to FIG. 6. Each of the first and second circuit sections 10 and 20 includes at least one inductor and at least one capacitor. In the example embodiment, the first circuit section 10 includes inductors L1 and L2 and a capacitor C1. The second circuit section 20 includes inductors L3 and L4 and a capacitor C2.

The inductors L1 and L2 are disposed in the first region R1. The inductor L2 is disposed between the second structure 9 and the side surface 50C. The inductor L1 is disposed between the inductor L2 and the side surface 50F and between the first structure 8 and the side surface 50C.

The inductors L3 and L4 are disposed in the second region R2. The inductor L3 is disposed between the second structure 9 and the side surface 50D. The inductor L4 is disposed between the inductor L3 and the side surface 50F and between the first structure 8 and the side surface 50D.

The first structure 8 is disposed between the inductor L1 and the inductor L4 when seen in the Z direction. The second structure 9 is disposed between the inductor L2 and the inductor L3 when seen in the Z direction.

The capacitor C1 is disposed between the inductor L1 and the second surface 50B. The capacitor C2 is disposed between the inductor L4 and the second surface 50B.

The first main body 1 further includes a ground conductor layer 91 connected to the ground. The ground conductor layer 91 is electrically connected to at least one of the electrodes 112, 114, 116, 118, or 119 that are connected to the ground.

The first and second structures 8 and 9 are connected to the ground conductor layer 91. In the example embodiment, in particular, at least one of the plurality of first through holes 71 and at least one of the plurality of second through holes 72 are connected to the ground conductor layer 91.

The ground conductor layer 91 overlaps at least a part of at least one of the first circuit section 10 or the second circuit section 20 when seen in the Z direction. In the example embodiment, in particular, the ground conductor layer 91 overlaps each of the inductors L1 to L4 entirely when seen in the Z direction.

The first main body 1 further includes capacitor conductor layers 92 and 93 disposed in the stack 50. Each of the capacitor conductor layers 92 and 93 faces the ground conductor layer 91 via at least one dielectric layer. The capacitor C1 includes the ground conductor layer 91, the capacitor conductor layer 92, and the at least one dielectric layer interposed between the ground conductor layer 91 and the capacitor conductor layer 92. The capacitor C2 includes the ground conductor layer 91, the capacitor conductor layer 93, and at least one dielectric layer interposed between the ground conductor layer 91 and the capacitor conductor layer 93. The capacitor conductor layer 92 is disposed between the inductor L1 and the ground conductor layer 91. The capacitor conductor layer 93 is disposed between the inductor L4 and the ground conductor layer 91.

The first main body 1 may further include a third structure (not shown) that separates a part of the first circuit section 10 from a part of the third circuit section 30, and a fourth structure (not shown) that separates a part of the second circuit section 20 from another part of the third circuit section 30. The third and fourth structures may be directly or indirectly connected to the ground conductor layer 91. Furthermore, the third and fourth structures may or do not have to be directly connected to each other.

Next, features of the first and second structures 8 and 9 and the second main body 2 will be described with reference to FIG. 2 to FIG. 5. As described above, the first to fourth terminals 2a, 2b, 2c, and 2d of the second main body 2 are respectively connected to the electrode pads 121, 122, 123, and 124 of the first main body 1 via the conductive bonding material. In addition, the second structure 9 is disposed between the electrode pad 121 and the electrode pad 124 and between the electrode pad 122 and the electrode pad 123 when seen in the Z direction. Therefore, the second structure 9 is disposed between the first terminal 2a and the fourth terminal 2d and between the second terminal 2b and the third terminal 2c when seen in the Z direction.

In addition, the electrode pads 121 and 122 are disposed forward of the second structure 9 in the −X direction when seen in the Z direction. Therefore, the first and second terminals 2a and 2b are disposed forward of the second structure 9 in the −X direction when seen in the Z direction.

Furthermore, the electrode pads 123 and 124 are disposed forward of the second structure 9 in the X direction when seen in the Z direction. Therefore, the third and fourth terminals 2c and 2d are disposed forward of the second structure 9 in the X direction when seen in the Z direction.

As described above, the first sub-circuit section 41 is provided between the first terminal 2a and the second terminal 2b in the circuit configuration. Although not shown in the drawings, at least a part of the first sub-circuit section 41 is disposed forward of the second structure 9 in the −X direction when seen in the Z direction.

In addition, as described above, the second sub-circuit section 42 is provided between the third terminal 2c and the fourth terminal 2d in the circuit configuration. Although not shown in the drawings, at least a part of the second sub-circuit section 42 is disposed forward of the second structure 9 in the X direction when seen in the Z direction.

In FIG. 4, a rectangular region denoted by the reference sign R20 indicates a region located between the first sub-circuit section 41 and the second sub-circuit section 42 in the second main body 2. The region R20 may be a three-dimensional region or a planar region. In addition, the region R20 may be located between a part of the first sub-circuit section 41 and a part of the second sub-circuit section 42. The specific second conductor layer 62 of the second structure 9 overlaps the region R20 when seen in the Z direction.

As shown in FIG. 4, the second structure 9 may protrude outside the second main body 2, i.e., the Y direction side of the second main body 2 and the −Y direction side of the second main body 2, when seen in the Z direction.

The specific first conductor layer 61 of the first structure 8 does not overlap the region R20 when seen in the Z direction. Note that as long as the requirement that the specific first conductor layer 61 does not overlap the region R20 is satisfied, the first structure 8 may or does not have to overlap the second main body 2 when seen in the Z direction. As shown in FIG. 4, in the example embodiment, the specific first conductor layer 61 of the first structure 8 does not overlap the second main body 2 when seen in the Z direction.

Next, features of the inductors L1 to L4 will be described with reference to FIG. 5 and FIG. 6. The inductor L1 includes at least one inductor conductor layer wound around an axis extending in the direction parallel to the stacking direction such that an opening surrounded by the inductor L1 is formed. Hereinafter, an opening surrounded by the inductor L1 or by the at least one inductor conductor layer of the inductor L1 will be referred to as an opening of the inductor L1. The opening of the inductor L1 is directed to the first surface 50A of the stack 50. In addition, the opening of the inductor L1 is located entirely in the first region R1. Hereinafter, for an inductor other than the inductor L1, an opening surrounded by the inductor or by the at least one inductor conductor layer of the inductor will be referred to as an opening of the inductor.

Similarly, the inductors L2, L3, and L4 each include at least one inductor conductor layer wound around an axis extending in the direction parallel to the stacking direction such that openings surrounded by the inductors L2, L3, and L4 respectively are formed. The openings of the inductors L2, L3, and L4 are directed to the first surface 50A of the stack 50. The opening of the inductor L2 is located entirely in the first region R1. The openings of the inductors L3 and L4 are located entirely in the second region R2.

The inductor L1 includes, as the at least one inductor conductor layer, a plurality of inductor conductor layers 81 disposed at a distance in the stacking direction. Each of the plurality of inductor conductor layers 81 is wound around an axis extending in the direction parallel to the stacking direction so as to surround the opening of the inductor L1. The first main body 1 further includes a conductor layer 85 connected to a first specific inductor conductor layer 81 closest to the first surface 50A of the plurality of inductor conductor layers 81, and a through hole T1 connecting the conductor layer 85 and the electrode pad 121. In FIG. 5, the boundary between the first specific inductor conductor layer 81 and the conductor layer 85 is indicated by a dotted line.

The inductor L1 may or does not have to be connected to the capacitor C1. When the inductor L1 is connected to the capacitor C1, the first main body 1 may further include a through hole, not shown, that connects the capacitor conductor layer 92 and a second specific inductor conductor layer 81 closest to the second surface 50B of the plurality of inductor conductor layers 81.

The inductor L2 includes, as the at least one inductor conductor layer, a plurality of inductor conductor layers 82 disposed at a distance in the stacking direction. Each of the plurality of inductor conductor layers 82 is wound around an axis extending in the direction parallel to the stacking direction so as to surround the opening of the inductor L2. The first main body 1 further includes a conductor layer 86 connected to a first specific inductor conductor layer 82 closest to the first surface 50A of the plurality of inductor conductor layers 82, and a through hole T2 connecting the conductor layer 86 and the electrode pad 122. In FIG. 5, the boundary between the inductor conductor layer 82 and the conductor layer 86 is indicated by a dotted line.

The inductor L2 may or does not have to be connected to the ground. When the inductor L2 is connected to the ground, the first main body 1 may further include a plurality of through holes, not shown, that connect the ground conductor layer 91 and a second specific inductor conductor layer 82 closest to the second surface 50B of the plurality of inductor conductor layers 82.

The inductor L3 includes, as the at least one inductor conductor layer, a plurality of inductor conductor layers 83 disposed at a distance in the stacking direction. Each of the plurality of inductor conductor layers 83 is wound around an axis extending in the direction parallel to the stacking direction so as to surround the opening of the inductor L3. The first main body 1 further includes a conductor layer 87 connected to a first specific inductor conductor layer 83 closest to the first surface 50A of the plurality of inductor conductor layers 83, and a through hole T3 connecting the conductor layer 87 and the electrode pad 123. In FIG. 5, the boundary between the inductor conductor layer 83 and the conductor layer 87 is indicated by a dotted line.

The inductor L3 may or does not have to be connected to the ground. When the inductor L3 is connected to the ground, the first main body 1 may further include a plurality of through holes, not shown, that connect the ground conductor layer 91 and a second specific inductor conductor layer 83 closest to the second surface 50B of the plurality of inductor conductor layers 83.

The inductor L4 includes, as the at least one inductor conductor layer, a plurality of inductor conductor layers 84 disposed at a distance in the stacking direction. Each of the plurality of inductor conductor layers 84 is wound around an axis extending in the direction parallel to the stacking direction so as to surround the opening of the inductor L4. The first main body 1 further includes a conductor layer 88 connected to a first specific inductor conductor layer 84 closest to the first surface 50A of the plurality of inductor conductor layers 84, and a through hole T4 connecting the conductor layer 88 and the electrode pad 124. In FIG. 5, the boundary between the inductor conductor layer 84 and the conductor layer 88 is indicated by a dotted line.

The inductor L4 may or does not have to be connected to the capacitor C2. When the inductor L4 is connected to the capacitor C2, the first main body 1 may further include a through hole, not shown, that connects the capacitor conductor layer 93 and a second specific inductor conductor layer 84 closest to the second surface 50B of the plurality of inductor conductor layers 84.

The inductor L1 is connected to the first sub-circuit section 41 of the second main body 2 via the conductor layer 85, the through hole T1, the electrode pad 121, and the first terminal 2a. The inductor L2 is connected to the first sub-circuit section 41 of the second main body 2 via the conductor layer 86, the through hole T2, the electrode pad 122, and the second terminal 2b. The inductor L3 is connected to the second sub-circuit section 42 of the second main body 2 via the conductor layer 87, the through hole T3, the electrode pad 123, and the third terminal 2c. The inductor L4 is connected to the second sub-circuit section 42 of the second main body 2 via the conductor layer 88, the through hole T4, the electrode pad 124, and the fourth terminal 2d.

The plurality of inductor conductor layers 81 of the inductor L1, the specific first conductor layer 61, and the plurality of inductor conductor layers 84 of the inductor L4 are arranged in this order along a first direction orthogonal to the stacking direction. In the example embodiment, in particular, the plurality of inductor conductor layers 81, the specific first conductor layer 61, and the plurality of inductor conductor layers 84 are arranged in this order along the X direction. The dimension of the specific first conductor layer 61 in a second direction (the Y direction) orthogonal to each of the stacking direction and the first direction (the X direction) may be larger than the dimension of the opening surrounded by each of the plurality of the inductor conductor layers 81 in the second direction (the dimension in the Y direction) and the dimension of the opening surrounded by each of the plurality of inductor conductor layers 84 in the second direction (the dimension in the Y direction).

In addition, the plurality of inductor conductor layers 82 of the inductor L2, the specific second conductor layer 62, and the plurality of inductor conductor layers 83 of the inductor L3 may be arranged in this order along the first direction orthogonal to the stacking direction. In the example embodiment, in particular, the plurality of inductor conductor layers 82, the specific second conductor layer 62, and the plurality of inductor conductor layers 83 are arranged in this order along the X direction. The dimension of the specific second conductor layer 62 in the second direction (the Y direction) orthogonal to each of the stacking direction and the first direction (the X direction) may be larger than the dimension of the opening surrounded by each of the plurality of inductor conductor layers 82 in the second direction (the dimension in the Y direction) and the dimension of the opening surrounded by each of the plurality of inductor conductor layers 83 in the second direction (the dimension in the Y direction).

Next, the operation and effects of the electronic component 100 according to the example embodiment will be described. The first main body 1 includes the first and second circuit sections 10 and 20, and the first and second structures 8 and 9. The second main body 2 includes the first and second sub-circuit sections 41 and 42. The first sub-circuit section 41 and the second sub-circuit section 42 are electrically separated from each other. The first structure 8 includes a specific first conductor layer 61 disposed between the first circuit section 10 and the second circuit section 20 when seen in the Z direction. The second structure 9 includes a specific second conductor layer 62 overlapping the region R20 located between the first sub-circuit section 41 and the second sub-circuit section 42 when seen in the Z direction. The specific first conductor layer 61 is not directly connected to the specific second conductor layer 62. In the example embodiment, in particular, the plurality of first conductor layers 61 other than the specific first conductor layer 61 are not directly connected to the plurality of second conductor layers 62 including the specific second conductor layer 62. Thus, according to the example embodiment, deterioration of the characteristics associated with downsizing can be suppressed.

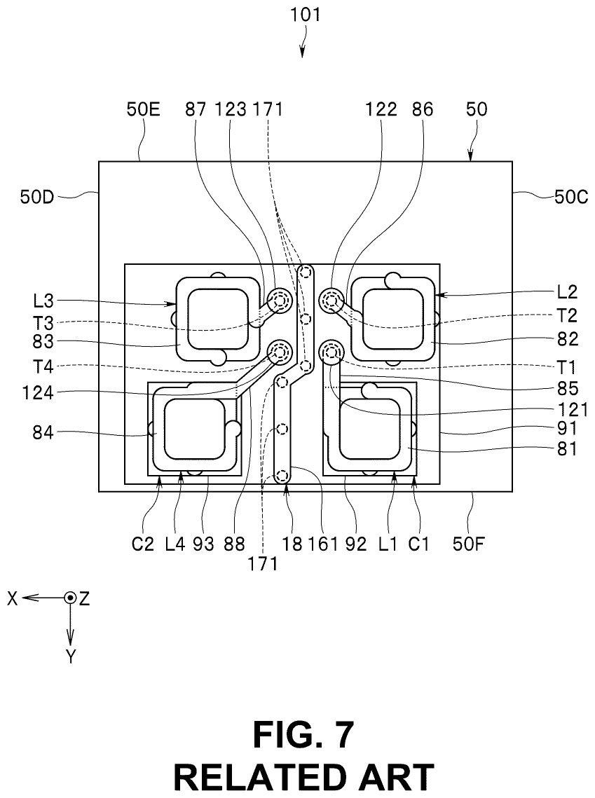

Hereinafter, the effects of the electronic component 100 according to the example embodiment will be described in comparison with an electronic component of a comparative example. First, the electronic component of the comparative example will be described. FIG. 7 is a plan view showing a part of a first main body of the electronic component of the comparative example.

A configuration of the electronic component of the comparative example is different from the configuration of the electronic component 100 according to the example embodiment in the following points. The electronic component of the comparative example includes a first main body 101, instead of the first main body 1 in the example embodiment. The first main body 101 includes a structure 18 connected the ground, instead of the first and second structures 8 and 9 in the example embodiment. The structure 18 includes a plurality of through holes 171, and a plurality of conductor layers 161 electrically connected to the plurality of through holes 171. Other configuration in the electronic component of the comparative example are similar to the configuration of the electronic component 100 according to the example embodiment.

Each of the plurality of conductor layers 161 includes a first part, a second part, and a third part connecting the first part and the second part. In addition, the plurality of conductor layers 161 include a specific conductor layer 161 closest to the first surface 50A of the stack 50. The shape and the position of the first part of the specific conductor layer 161 are substantially the same as the shape and the position of the specific first conductor layer 61 of the first structure 8 in the example embodiment. The shape and the position of the second part of the specific conductor layer 161 are substantially the same as the shape and the position of the specific second conductor layer 62 of the second structure 9 in the example embodiment.

The shapes of the first to third parts of each of the plurality of conductor layers 161 other than the specific conductor layer 161 are the same as the shapes of the first to third parts of the specific conductor layer 161. The positions of the first to third parts of each of the plurality of conductor layers 161 other than the specific conductor layer 161 are the same as the positions of the first to third parts of the specific conductor layer 161 other than the position in the stacking direction (the direction parallel to the Z direction).

In the comparative example, the first part of each of the plurality of the conductor layers 161 is disposed between the inductor L1 of the first circuit section 10 and the inductor L4 of the second circuit section 20 of the first main body 101. The second part of each of the plurality of conductor layers 161 is disposed between the inductor L2 of the first circuit section 10 and the inductor L3 of the second circuit section 20 of the first main body 101. In addition, the second part of each of the plurality of conductor layers 161 overlaps the region R20 (see FIG. 4) located between the first sub-circuit section 41 and the second sub-circuit section 42 in the second main body 2 when seen in the Z direction. The second part of each of the plurality of conductor layers 161 is disposed between at least a part of the first sub-circuit section 41 and at least a part of the second sub-circuit section 42 when seen in the Z direction.

The first sub-circuit section 41 and the second sub-circuit section 42 are electrically separated from each other. In addition, the second part of each of the plurality of conductor layers 161 prevents the inductor L2 connected to the first sub-circuit section 41 and the inductor L3 connected to the second sub-circuit section 42 from coupling to each other. This achieves the desired characteristics.

Incidentally, when the stack 50 is downsized, depending on the shape and the position of the inductor L1, the inductor L1 is coupled to the first part of each of the plurality of conductor layers 161. In the comparative example, since the first part and the second part are connected by the third part in each of the plurality of conductor layers 161, unintended flowing of a current may occur between the inductor L1 and the inductor L2 and between the inductor L1 and the inductor L3. Furthermore, unintended flowing of a current may occur also between the inductor L1 and the second sub-circuit section 42. As a result, the isolation characteristics between the first filter 4 and the second filter 5 may deteriorate.

Similarly, when the stack 50 is downsized, depending on the shape and the position of the inductor L4, the inductor L4 is coupled to the first part of each of the plurality of conductor layers 161. In the comparative example, since the first part and the second part are connected by the third part in each of the plurality of conductor layers 161, unintended flowing of a current may occur between the inductor L2 and the inductor L4 and between the inductor L3 and the inductor L4. Furthermore, unintended flowing of a current may occur also between the inductor L4 and the first sub-circuit section 41. As a result, the isolation characteristics between the first filter 4 and the second filter 5 may deteriorate.

In contrast, in the example embodiment, the specific first conductor layer 61 of the first structure 8 is not directly connected to the specific second conductor layer 62 of the second structure 9, as described above. In the example embodiment, in particular, the plurality of first conductor layers 61 other than the specific first conductor layer 61 are not directly connected to the plurality of second conductor layers 62 including the specific second conductor layer 62. Thus, according to the example embodiment, unintended flowing of a current associated with downsizing of the stack 50 can be suppressed. As a result, according to the example embodiment, deterioration of the isolation characteristics associated with downsizing can be suppressed.

Next, a result of a simulation examining isolation characteristics of the electronic component 100 according to the example embodiment will be described. A model of an example used in the simulation will initially be described. The model of the example is a model of the electronic component 100 according to the example embodiment. In the simulation, the first circuit section 10 and the first sub-circuit section 41 of the first filter 4, the second circuit section 20 and the second sub-circuit section 42 of the second filter 5, and the third circuit section 30 of the third filter 6 were designed to make the model of the example operate as a branching filter.

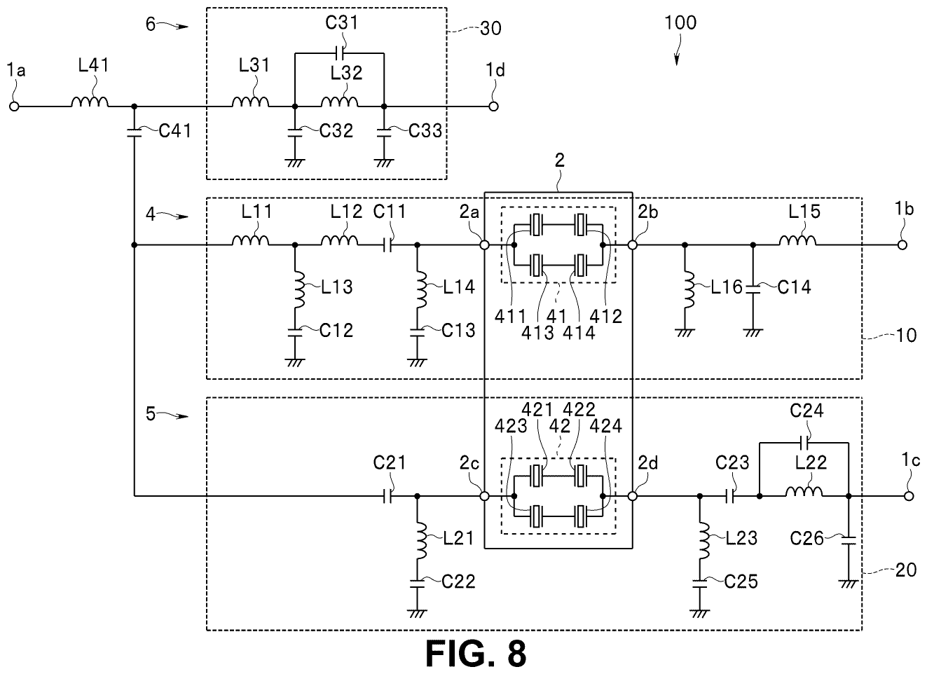

FIG. 8 is a circuit diagram showing a circuit configuration of the model of the example. The model of the example includes an inductor L41 and a capacitor C41 in addition to the first to third filters 4 to 6. One end of the inductor L41 is connected to the common terminal 1a. One ends of the third filter 6 and the capacitor C41 are connected to the other end of the inductor L41. The other end of the third filter 6 is connected to the third signal terminal 1d.

One ends of the first filter 4 and the second filter 5 are connected to the other end of the capacitor C41. The other end of the first filter 4 is connected to the first signal terminal 1b. The other end of the second filter 5 is connected to the second signal terminal 1c.

The third circuit section 30 of the third filter 6 includes inductors L31 and L32, and capacitors C31, C32, and C33. One end of the inductor L31 is connected to the other end of the inductor L41. One end of the inductor L32 is connected to the other end of the inductor L31. The other end of the inductor L32 is connected to the third signal terminal 1d.

The capacitor C31 is connected in parallel to the inductor L32. One end of the capacitor C32 is connected to a connection point of the inductor L31 and the inductor L32. One end of the capacitor C33 is connected to the other end of the inductor L32. The other ends of the capacitors C32 and C33 are connected to the ground.

The first circuit section 10 of the first filter 4 includes inductors L11, L12, L13, L14, L15, and L16, and capacitors C11, C12, C13, and C14. The first sub-circuit section 41 of the first filter 4 includes four acoustic wave elements 411, 412, 413, and 414.

One end of the inductor L11 is connected to the other end of the capacitor C41. One end of the inductor L12 is connected to the other end of the inductor L11. One end of the capacitor C11 is connected to the other end of the inductor L12. The other end of the capacitor C11 is connected to the first terminal 2a of the second main body 2.

One end of the inductor L13 is connected to a connection point of the inductor L11 and the inductor L12. One end of the capacitor C12 is connected to the other end of the inductor L13. The other end of the capacitor C12 is connected to the ground.

One end of the inductor L14 is connected to the other end of the capacitor C11 and the first terminal 2a of the second main body 2. One end of the capacitor C13 is connected to the other end of the inductor L14. The other end of the capacitor C13 is connected to the ground.

One ends of the acoustic wave elements 411 and 413 are connected to the first terminal 2a. One end of the acoustic wave element 412 is connected to the other end of the acoustic wave element 411. One end of the acoustic wave element 414 is connected to the other end of the acoustic wave element 413. The other ends of the acoustic wave elements 412 and 414 are connected to the second terminal 2b of the second main body 2.

One ends of the inductors L15 and L16 are connected to the second terminal 2b. The other end of the inductor L15 is connected to the first signal terminal 1b. The other end of the inductor L16 is connected to the ground.

One end of the capacitor C14 is connected to one end of the inductor L15. The other end of the capacitor C14 is connected to the ground.

The second circuit section 20 of the second filter 5 includes inductors L21, L22, and L23, and capacitors C21, C22, C23, C24, C25, and C26. The second sub-circuit section 42 of the second filter 5 includes four acoustic wave elements 421, 422, 423, and 424.

One end of the capacitor C21 is connected to the other end of the capacitor C41. The other end of the capacitor C21 and one end of the inductor L21 are connected to the third terminal 2c of the second main body 2. One end of the capacitor C22 is connected to the other end of the inductor L21. The other end of the capacitor C22 is connected to the ground.

One ends of the acoustic wave elements 421 and 423 are connected to the third terminal 2c. One end of the acoustic wave element 422 is connected to the other end of the acoustic wave element 421. One end of the acoustic wave element 424 is connected to the other end of the acoustic wave element 423. The other ends of the acoustic wave elements 422 and 424 are connected the fourth terminal 2d of the second main body 2.

One ends of the capacitor C23 and the inductor L23 are connected to the fourth terminal 2d. One end of the inductor L22 is connected to the other end of the capacitor C23. The other end of the inductor L22 is connected to the second signal terminal 1c. The capacitor C24 is connected in parallel to the inductor L22.

One end of the capacitor C25 is connected to the other end of the inductor L23. The other end of the capacitor C25 is connected to the ground.

One end of the capacitor C26 is connected to the other end of the inductor L22. The other end of the capacitor C26 is connected to the ground.

The plurality of inductors and the plurality of capacitors shown in FIG. 8 are configured using the plurality of dielectric layers, the plurality of conductor layers, and the plurality of through holes of the stack 50.

Note that the inductor L14 and the inductor L16 may correspond respectively to the “inductor L1” and the “inductor L2” shown in FIG. 5 and FIG. 6. In this case, the capacitor C13 may correspond to the “capacitor C1”shown in FIG. 5 and FIG. 6.

In addition, the inductor L21 and the inductor L23 may correspond respectively to the “inductor L3” and the “inductor L4” shown in FIG. 5 and FIG. 6. In this case, the capacitor C25 may correspond to the “capacitor C2”shown in FIG. 5 and FIG. 6.

Next, a model of the comparative example used in the simulation will be described. The model of the comparative example is a model of the electronic component of the comparative example. In the model of the comparative example, in particular, the structure 18 connected to the ground is provided, instead of the first and second structures 8 and 9. The circuit configuration of the model of the comparative example is the same as the circuit configuration of the model of the example shown in FIG. 8.

Next, the result of the simulation will be described. In the simulation, the model of the example and the model of the comparative example were each examined for the frequency characteristics of isolation between the first and second filters 4 and 5. Note that the isolation in the simulation is defined as follows. Suppose that when a high frequency signal of power P1 is input to the first signal terminal 1b, a signal of power P2 is output from the second signal terminal 1c. Isolation I is defined by the following Equation (1):

$$I = 10 log ( P 2 / P 1 ) \qquad ( 1 )$$

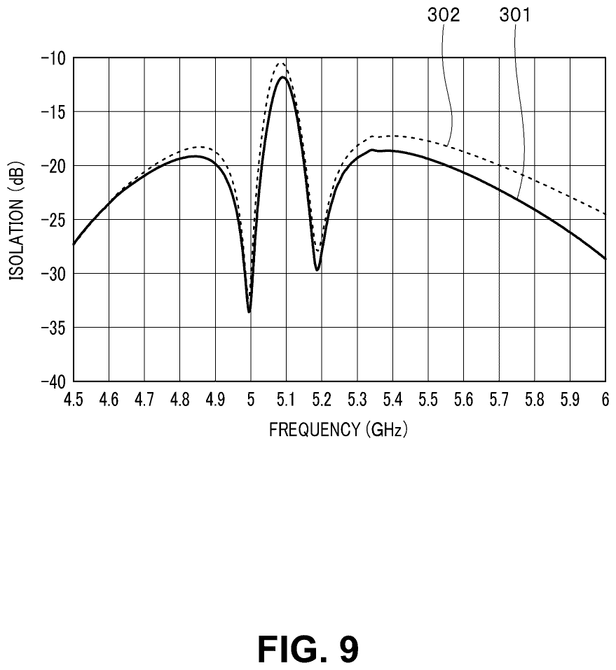

FIG. 9 is a characteristic chart showing the frequency characteristics of the isolation. In FIG. 9, the horizontal axis indicates the frequency, and the vertical axis indicates the isolation. In FIG. 9, the curve denoted by the reference sign 301 represents the frequency characteristics of the isolation of the model of the example. The curve denoted by the reference sign 302 represents the frequency characteristics of the isolation of the model of the comparative example. As shown in FIG. 9, the model of the example (301) provides an isolation of a large absolute value compared to the model of the comparative example (302). As seen from the result of the simulation, according to the example embodiment, the isolation can be sufficiently increased by the first and the second structures 8 and 9.

Note that the disclosure is not limited to the foregoing example embodiment, and various modifications may be made thereto. For example, the electronic component of the disclosure may be a diplexer including two filters, or may be a band-pass filter including a plurality of filters.

As described above, an electronic component according to one embodiment of the disclosure includes a first main body including a plurality of dielectric layers stacked together; and a second main body mounted on the first main body. The first main body further includes a first circuit section, a second circuit section, and a first structure and a second structure each connected to a ground. The second main body includes a first sub-circuit section and a second sub-circuit section electrically separated from each other. The first structure includes a first conductor layer located between the first circuit section and the second circuit section when viewed in a stacking direction of the plurality of dielectric layers. The second structure includes a second conductor layer overlapping a region located between the first sub-circuit section and the second sub-circuit section when viewed in the stacking direction. The first conductor layer is not directly connected to the second conductor layer.

In the electronic component according to one embodiment of the disclosure, the first conductor layer does not have to overlap the second main body when viewed in the stacking direction.

In the electronic component according to one embodiment of the disclosure, each of the first structure and the second structure may further include a plurality of through holes, and a plurality of conductor layers electrically connected to the plurality of through holes. The plurality of conductor layers of the first structure may include the first conductor layer. The plurality of the conductor layers of the second structure may include the second conductor layer.

In the electronic component according to one embodiment of the disclosure, the first main body may further include a ground conductor layer connected to the ground. The first structure and the second structure may be disposed between the second main body and the ground conductor layer in the stacking direction, and may be connected to the ground conductor layer. The ground conductor layer may overlap at least a part of at least one of the first circuit section or the second circuit section when viewed in the stacking direction. The first circuit section may include a first inductor including a first inductor conductor layer wound around a first axis parallel to the stacking direction. The second circuit section may include a second inductor including a second inductor conductor layer wound around a second axis parallel to the stacking direction. The first inductor conductor layer, the first conductor layer, and the second inductor conductor layer may be arranged in this order along a first direction orthogonal to the stacking direction. A dimension of the first conductor layer in a second direction orthogonal to each of the stacking direction and the first direction may be greater than a dimension of an opening surrounded by the first inductor conductor layer in the second direction and a dimension of an opening surrounded by the second inductor conductor layer in the second direction.

In the electronic component according to one embodiment of the disclosure, the first circuit section may be connected to the first sub-circuit section. The second circuit section may be connected to the second sub-circuit section.

The electronic component according to one embodiment of the disclosure may further include a first filter configured to selectively pass a signal of a frequency within a first passband; and a second filter configured to selectively pass a signal of a frequency within a second passband different from the first passband. The first filter may include the first circuit section and the first sub-circuit section. The second filter may include the second circuit section and the second sub-circuit section.

The electronic component according to one embodiment of the disclosure may further include a third filter configured to selectively pass a signal of a frequency within a third passband different from each of the first passband and the second passband.

In the electronic component according to one embodiment of the disclosure, each of the first conductor layer and the second conductor layer may includes a part extending along a same direction orthogonal to the stacking direction.

In the electronic component of the disclosure, the first conductor layer of the first structure is not directly connected to the second conductor layer of the second structure. Thus, according to the disclosure, deterioration of the characteristics associated with downsizing can be suppressed.

It is apparent that the disclosure can be carried out in various forms and modifications in the light of the foregoing descriptions. Accordingly, within the scope of the following claims and equivalents thereof, the disclosure can be carried out in forms other than the foregoing example embodiments.

1. An electronic component comprising:
a first main body including a plurality of dielectric layers stacked together; and
a second main body mounted on the first main body, wherein:
the first main body further includes a first circuit section, a second circuit section, and a first structure and a second structure each connected to a ground;
the second main body includes a first sub-circuit section and a second sub-circuit section electrically separated from each other;
the first structure includes a first conductor layer located between the first circuit section and the second circuit section when viewed in a stacking direction of the plurality of dielectric layers;
the second structure includes a second conductor layer overlapping a region located between the first sub-circuit section and the second sub-circuit section when viewed in the stacking direction; and
the first conductor layer is not directly connected to the second conductor layer.

2. The electronic component according to claim 1, wherein the first conductor layer does not overlap the second main body when viewed in the stacking direction.

3. The electronic component according to claim 1, wherein:
each of the first structure and the second structure further includes a plurality of through holes, and a plurality of conductor layers electrically connected to the plurality of through holes;
the plurality of conductor layers of the first structure include the first conductor layer; and
the plurality of the conductor layers of the second structure include the second conductor layer.

4. The electronic component according to claim 1, wherein:
the first main body further includes a ground conductor layer connected to the ground; and
the first structure and the second structure are disposed between the second main body and the ground conductor layer in the stacking direction, and are connected to the ground conductor layer.

5. The electronic component according to claim 4, wherein the ground conductor layer overlaps at least a part of at least one of the first circuit section or the second circuit section when viewed in the stacking direction.

6. The electronic component according to claim 5, wherein:
the first circuit section includes a first inductor including a first inductor conductor layer wound around a first axis parallel to the stacking direction;
the second circuit section includes a second inductor including a second inductor conductor layer wound around a second axis parallel to the stacking direction;
the first inductor conductor layer, the first conductor layer, and the second inductor conductor layer are arranged in this order along a first direction orthogonal to the stacking direction; and
a dimension of the first conductor layer in a second direction orthogonal to each of the stacking direction and the first direction is greater than a dimension of an opening surrounded by the first inductor conductor layer in the second direction and a dimension of an opening surrounded by the second inductor conductor layer in the second direction.

7. The electronic component according to claim 1, wherein:
the first circuit section is connected to the first sub-circuit section; and
the second circuit section is connected to the second sub-circuit section.

8. The electronic component according to claim 7, further comprising:
a first filter configured to selectively pass a signal of a frequency within a first passband; and
a second filter configured to selectively pass a signal of a frequency within a second passband different from the first passband, wherein:
the first filter includes the first circuit section and the first sub-circuit section; and
the second filter includes the second circuit section and the second sub-circuit section.

9. The electronic component according to claim 8, further comprising a third filter configured to selectively pass a signal of a frequency within a third passband different from each of the first passband and the second passband.

10. The electronic component according to claim 1, wherein each of the first conductor layer and the second conductor layer includes a part extending along a same direction orthogonal to the stacking direction.
